(19) United States
(12) Patent Application Publication
(10) Pub. No.: US 2020/0058521 A1
(43) Pub. Date: Feb. 20, 2020

(54) WAFER CLEANING WITH DYNAMIC CONTACTS

(71) Applicant: Taiwan Semiconductor Manufacturing Co., Ltd., Hsinchu City (TW)

(72) Inventors: Kun-Hsiung SHIH, Hsin-Chu (TW); Bo-Chen CHEN, Hsin-Chu (TW); Yung-Li TSAI, Houlong Town (TW); Chui-Ya PENG, Hsinchu City (TW)

(21) Appl. No.: 16/539,265

(22) Filed: Aug. 13, 2019

Related U.S. Application Data
(60) Provisional application No. 62/719,560, filed on Aug. 17, 2018.

(51) Int. Cl. H01L 21/67; H01L 21/02; H01L 21/687

(52) U.S. Cl. CPC H01L 21/67051; H01L 21/68764; H01L 21/0209; H01L 21/02052

(57) ABSTRACT

In an embodiment, a system includes: a pedestal configured to secure a wafer; a nozzle configured to deposit a cleaning solution on the wafer disposed on the pedestal during a cleaning session; and a plurality of contacts configured to secure the wafer to the pedestal while the cleaning solution is deposited on the wafer, wherein a first subset of the plurality of contacts is configured to contact the wafer at a first time interval and a second subset of the plurality of contacts is configured to contact the wafer at a second time interval.

### CROSS-REFERENCE TO RELATED APPLICATION

The present application claims priority to U.S. Provisional Patent Application No. 62/719,560, filed on Aug. 17, 2018, which is incorporated by reference herein in its entirety.

### BACKGROUND

With advances of electronic products, semiconductor technology has been widely applied in manufacturing memories, central processing units (CPUs), liquid crystal displays (LCDs), light emission diodes (LEDs), laser diodes and other devices or chip sets. In order to achieve high-integration and high-speed requirements, dimensions of semiconductor integrated circuits have been reduced and various materials and techniques have been proposed to achieve these requirements and overcome obstacles during manufacturing. Controlling the conditions of processing wafers within chambers or tanks is an important part of semiconductor fabrication technology.

One of the important concerns of semiconductor fabrication technology is particles. Particles within process apparatus, such as chambers or wet benches, easily contaminate wafers processed therein. Typical manual cleaning of wafers may not be sufficient for particle decontamination. Therefore, conventional techniques to avoid particle contamination are not entirely satisfactory.

### BRIEF DESCRIPTION OF THE DRAWINGS

Aspects of the present disclosure are best understood from the following detailed description when read with the accompanying figures. It is noted that various features are not necessarily drawn to scale. In fact, the dimensions and geometries of the various features may be arbitrarily increased or reduced for clarity of discussion.

FIG. 1A is a perspective view block diagram of a dynamic contact cleaning chamber, in accordance with some embodiments.

FIG. 1B is a side view diagram of the dynamic contact cleaning chamber, in accordance with some embodiments.

FIG. 2A is a perspective view block diagram of the first subset of contacts at the first time interval, in accordance with some embodiments.

FIG. 2B is a perspective view block diagram of the second subset of contacts at the second time interval, in accordance with some embodiments.

FIG. 3 is a block diagram of a dynamic contact cleaning chamber functional module of the dynamic contact cleaning chamber, in accordance with some embodiments.

FIG. 4 is a flow chart of a dynamic contact cleaning chamber process, in accordance with some embodiments.

FIG. 5 is a flow chart of a process for securing a wafer with a next contact subset(s) in series, in accordance with some embodiments.

FIG. 6A illustrates a wafer secured with a first contact subset, in accordance with some embodiments.

FIG. 6B illustrates the wafer secured with the all contact subsets during an intermediate time interval, in accordance with some embodiments.

FIG. 6C illustrates the wafer secured with a transition subset distinct from the first contact subset and the second contact subset during an intermediate time interval, in accordance with some embodiments.

FIG. 7 illustrates a wafer secured with a first contact subset, in accordance with some embodiments.

FIG. 8 illustrates a wafer secured with a first contact subset, in accordance with some embodiments.

### DETAILED DESCRIPTION OF EXEMPLARY EMBODIMENTS

The following disclosure describes various exemplary embodiments for implementing different features of the subject matter. Specific examples of components and arrangements are described below to simplify the present disclosure. These are, of course, merely examples and are not intended to be limiting. For example, it will be understood that when an element is referred to as being “connected to” or “coupled to” another element, it may be directly connected to or coupled to the other element, or one or more intervening elements may be present.

In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the course of creating a multiple layer semiconductor device on a semiconductor wafer, each layer making up the device may be subjected to one or more deposition processes, for example using chemical vapor deposition (CVD) or physical vapor deposition (PVD), and usually including one or more etching procedures by either a dry (plasma) or wet (chemical) etching process. A condition in semiconductor manufacturing is the absence of contaminants on the wafer processing surface, since contaminants including, for example, microscopic particles, may interfere with and adversely affect subsequent processing steps leading to device degradation and ultimately semiconductor wafer rejection. Also, as semiconductor feature sizes decrease, the detrimental effect of particle contamination increases, requiring removal of ever smaller particles. For example, particles as small as 5 nanometers (nm) may be unacceptable in many semiconductor manufacturing processes. Thus, there may be a need for improved techniques for wafer cleaning to avoid particle contamination.

Systems and methods in accordance with various embodiments are directed to wafer cleaning with dynamic contacts that secure a wafer to a pedestal during wafer cleaning. The dynamic contacts may change contact positions on the wafer over time. In this manner, the points of contacts or contact positions on the wafer may change over time in a single continuous cleaning session. The contact positions may change by either the same contacts contacting the wafer at different contact positions or by utilizing different contacts that contact different contact positions at different times. It can be appreciated that a wafer may not be properly cleaned if the contact positions on the wafer are not released for cleaning at the contact positions (e.g., the contact positions themselves are not cleaned when used to contact the wafer). Accordingly, a wafer may have its contact positions cleaned when secured to a pedestal using dynamic contacts that change contact positions during a session of cleaning.

In various embodiments, the dynamic contacts may secure the wafer along a periphery (e.g., a circumference) of the wafer. For example, six dynamic contacts may contact the periphery of the wafer at six respective contact positions on the wafer. However, only three of the dynamic contacts may contact the wafer during certain intervals, or time periods (e.g., a first time period or a second time period) of the cleaning session. Optionally, in certain embodiments, all six dynamic contacts may contact the wafer for stability during the transition from utilizing a first subset of the six dynamic contacts to utilizing a second subset of the six dynamic contacts to secure the wafer on the pedestal. Accordingly, all six contact positions may be exposed for cleaning at some point during a single cleaning session.

In various embodiments, a nozzle may be configured to deposit a cleaning solution on a wafer disposed on a pedestal during a cleaning session. This cleaning solution may be deionized water, or may be based on hydrogen peroxide. At high pH values (basic) organic contamination and oxidizable particles may be removed by an oxidation process. At low pH (acidic) metal contamination may be desorbed from the water surface by forming a soluble complex.

In various embodiments, the cleaning solution may be one of a solution of hydrogen peroxide (H₂O₂) and sulfuric acid (H₂SO₄), a solution of hydrogen peroxide with choline ((CH₃)₃N(CH₂CH₂OH)OH), a solution of H₂O₂ and NH₄OH and a solution of H₂O₂ and HCl, a solution of a carboxylic group containing acid, such as citric acid, and deionized water. In addition, different cleaning solutions may be applied during a cleaning session, such as where after applying a first cleaning solution, the cleaning process is followed by a second cleaning solution of deionized water as a rinse and then the wafer is spun to dry. Other carboxylic cleaning solutions suitably include formic acid, acetic acid, propionic acid, valeric acid, oxalic acid, malonic acid, succinic acid, glutaric acid, maleic acid, fumaric acid, phthalic acid, glycolic acid, lactic acid, citric acid, tartaric acid, gluconic acid, and adipic acid.

In various embodiments, a cleaning session may include simultaneously rotating the wafer while a high pressure jet of cleaning solution is sprayed on a process surface of the wafer. For example, one or more jet spray nozzles may sweep a spray of pressurized cleaning solution over the wafer process surface of the wafer, which may be mounted on a pedestal. The pedestal may be an electrostatic pedestal in certain embodiments. The pedestal may include dynamic contacts configured to contact the wafer at the periphery of the wafer to help hold the wafer in place while the pedestal, attached to the rotatable shaft, is rotated by a variable speed motor. In operation, for example the pressurized spray of cleaning solution is preferably about 10 pound force per square inch (PSI) to about 20 PSI and is applied over the process surface of the wafer preferably rotated at speeds of about 200 to about 1000 rpm.

In certain embodiments, wafer cleaning may be performed in the context of a semiconductor manufacturing processes where chemical vapor deposition (CVD) and physical vapor deposition (PCD) processes may be performed. These CVD process may include, for example, plasma enhanced CVD (PECVD), low pressure CVD (LPCVD), atmospheric pressure CVD (APCVD), and high density plasma CVD (HDP-CVD). Also, these PVD process includes any PVD process including, for example, collimated sputtering (CS), ionized magnetron sputtering (IMS), and ion metal plasma (IMP). However, it will be appreciated that various embodiments of the present invention are applicable to any and all semiconductor manufacturing processes that may include wafer cleaning to reduce particulate contamination.

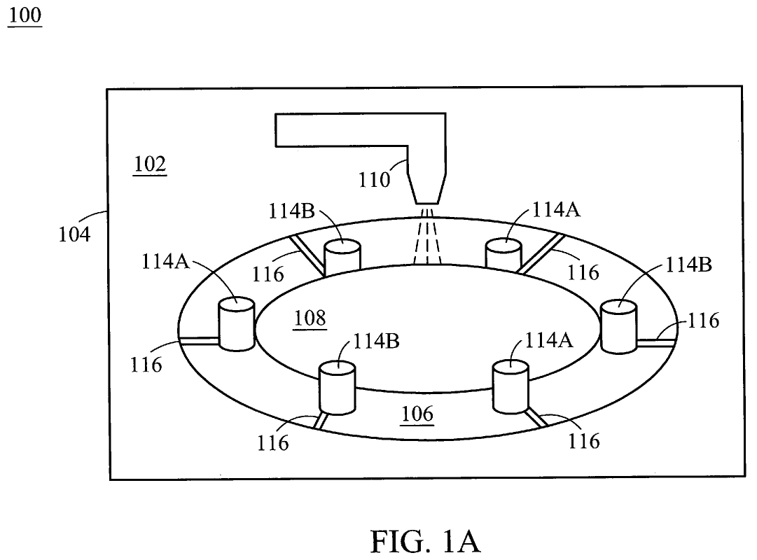

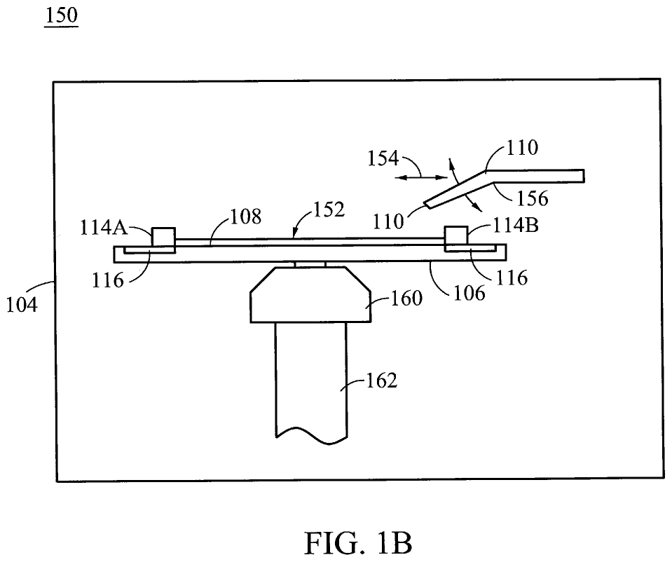

FIG. 1A is a perspective view block diagram of a dynamic contact cleaning chamber 100, in accordance with some embodiments. The dynamic contact cleaning chamber 100 may be defined by an enclosure 102 generally surrounded by walls 104 to define an enclosed space accessible by a portal (not illustrated and discussed further below). The dynamic contact cleaning chamber 100 may include a pedestal 106 on which a wafer 108 may be disposed. Also, in various embodiments, the pedestal 106 may be an electrostatic pedestal that may adhere the wafer 108 to the pedestal 106 via electrostatic forces. At least one nozzle 110 may be configured to dispense or deposit a cleaning solution 112 on the wafer 108 during a cleaning session.

The dynamic contact cleaning chamber 100 may include a plurality of contacts 114A, 114B configured to secure the wafer 108 to the pedestal 106 while the cleaning solution 112 is deposited on the wafer 108. The plurality of contacts 114A, 114B may include a first subset 114A and a second subset 114B. The first subset 114A of the plurality of contacts is configured to contact the wafer 108 at a first time interval. Also, the second subset 114B of the plurality of contacts is configured to contact the wafer 108 at a second time interval. It can be noted that, in the illustrated embodiment, the first subset 114A of the plurality of contacts comprise different contacts than the second subset 114B of the plurality of contacts. In various embodiments, the contacts 114A, 114B may be shaped as a cylinder (e.g., to be cylindrical in shape). Also, the contacts 114A, 114B may be configured to be moved by an actuator 116 that may move the contacts 114A, 114B from a contact position of contact to the wafer 108 and a non-contact position of non-contact with the wafer 108. The actuator may be any type of conventional actuator or device for movement of an object, such as shaft or a conveyor belt connected to the contacts 114A, 114B that moves the contacts 114A, 114B between the contact position and the non-contact position.

In certain embodiments, the first time interval and the second time interval are continuous. However, in other embodiments, an intermediate time interval may separate the first and second time interval. More specifically, each of the plurality of contacts 114A, 114B may be configured to contact the wafer 108 at the intermediate time interval interval between the first time interval and the second time interval to stabilize the wafer 108 during the transition between the first time interval and the second time interval. In the illustrated embodiment, each of the plurality of contacts 114A, 114B may be in contact with the wafer 108 during the intermediate time interval.

Each of the plurality of contacts 114A, 114B may contact the wafer 108 at respective contact positions (e.g., points of interface or contact between a contact 114A, 114B and the wafer 108). Stated another way, the first subset 114A of contacts may contact the wafer 108 at a first subset of contact positions and the second subset 114B of contacts may contact the wafer 108 at a second subset of contact positions. Accordingly, the wafer 108 may be cleaned along the second subset of contact positions during the first time interval. Also, the wafer 108 may be cleaned along the first subset of contact positions during the second time interval. Also, during the intermediate time interval, the contacts 114A, 114B may contact the wafer 108 at both the first subset of contact positions and the second subset of contact positions.

FIG. 1B is a side view diagram 150 of the dynamic contact cleaning chamber 100, in accordance with some embodiments. The pedestal 106 may rotate the wafer 108 while the high pressure jet of cleaning solution 112 is sprayed on a process surface 152 of the wafer 108. For example, at least one nozzle 110 may sweep a spray of pressurized cleaning solution 112 over the wafer process surface 152 of the wafer 108, which is mounted on the pedestal 106. In certain embodiments, the nozzle 110 may be configured to move over the wafer 108 in a lateral motion 154. In further embodiments, the nozzle 110 may be configured to pivot (e.g., along a pivoting joint 156) and position an end of the nozzle to scan across a diameter of the wafer 108.

Contacts 114A, 114B may be configured to contact the wafer 108 at the periphery (e.g., the circumference) of the wafer 108 to hold the wafer 108 in place. In various embodiments, the contacts 114A, 114B may be configured to be moved by the actuator 116 that may move the contacts 114A, 114B from a contact position of contact to the wafer 108 and a non-contact position of non-contact with the wafer 108. The actuator 116 may be, for example, a conveyor belt or shaft connected to the contacts 114A, 114B that moves the contacts 114A, 114B between the contact position and the non-contact position.

The pedestal 106 may be attached to a rotatable shaft rotated by a variable speed motor housed in shaft housings 160, 162. The rotatable shaft may be rotated by a variable speed motor. In operation, for example the pressurized spray of cleaning solution is preferably about 10 pound force per square inch (PSI) to about 20 PSI and is applied over the process surface of the wafer preferably rotated at speeds of about 200 to about 1000 rpm.

In various embodiments, the cleaning solution may be deionized water, or may be based on hydrogen peroxide. At high pH values (basic) organic contamination and oxidizable particles, may be removed by an oxidation process. At low pH (acidic) metal contamination may be desorbed from the water surface by forming a soluble complex.

In various embodiments, the cleaning solution may be one of a solution of hydrogen peroxide (H₂O₂) and sulfuric acid (H₂SO₄), a solution of hydrogen peroxide with choline ((CH₃)₃N(CH₂CH₂OH)OH), a solution of H₂O₂ and NH₄OH and a solution of H₂O₂ and HCl, a solution of a carboxylic group containing acid, such as citric acid, and deionized water. In addition, different cleaning solutions may be applied during a cleaning session, such as where after applying a first cleaning solution, the cleaning process is followed by application of a second cleaning solution of deionized water rinse.

In certain embodiments, wafer cleaning may be performed in the context of a semiconductor manufacturing processes where chemical vapor deposition (CVD) and physical vapor deposition (PCD) processes may be performed. These CVD process may include, for example, plasma enhanced CVD (PECVD), low pressure CVD (LPCVD), atmospheric pressure CVD (APCVD), and high density plasma CVD (HDP-CVD). Also, these PVD process includes any PVD process including, for example, collimated sputtering (CS), ionized magnetron sputtering (IMS), and ion metal plasma (IMP). However, it will be appreciated that various embodiments of the present invention are applicable to any and all semiconductor manufacturing processes to clean a wafer for reduction of particulate contamination.

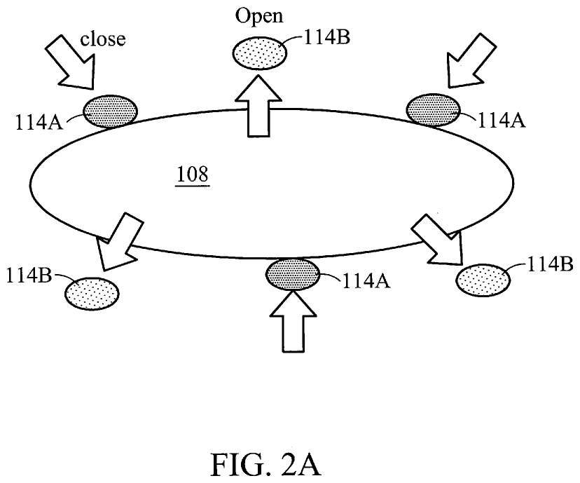

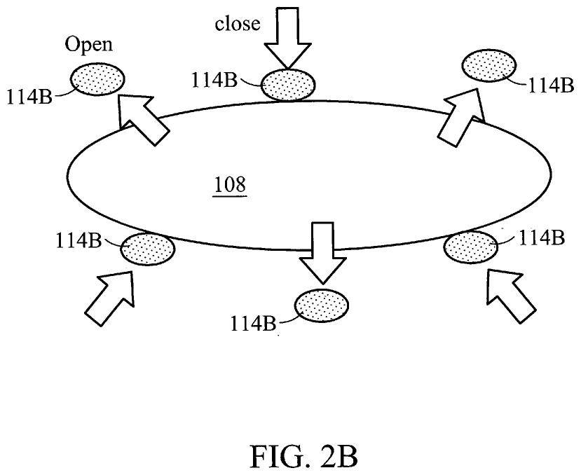

FIG. 2A is a perspective view block diagram of the first subset of contacts 114A at the first time interval, in accordance with some embodiments. As introduced above, the dynamic contact cleaning chamber may include a plurality of contacts 114A, 114B configured to secure the wafer 108 while the cleaning solution is deposited on the wafer 108. The plurality of contacts 114A, 114B may include a first subset 114A and a second subset 114B. The first subset 114A of the plurality of contacts is configured to contact the wafer 108 at a first time interval. Also, the second subset 114B of the plurality of contacts is configured to contact the wafer 108 at a second time interval. It can be noted that the first subset 114A of the plurality of contacts comprise different contacts than the second subset 114B of the plurality of contacts.

FIG. 2B is a perspective view block diagram of the second subset of contacts 114B at the second time interval, in accordance with some embodiments. As introduced above, the dynamic contact cleaning chamber may include a plurality of contacts 114A, 114B configured to secure the wafer 108 while the cleaning solution is deposited on the wafer 108. The plurality of contacts 114A, 114B may include a first subset 114A and a second subset 114B. The first subset 114A of the plurality of contacts is configured to contact the wafer 108 at a first time interval. Also, the second subset 114B of the plurality of contacts is configured to contact the wafer 108 at a second time interval. It can be noted that the first subset 114A of the plurality of contacts comprise different contacts than the second subset 114B of the plurality of contacts.

In certain embodiments, the first time interval and the second time interval are continuous. However, in other embodiments, an intermediate time interval may separate the first and second time interval. More specifically, each of the plurality of contacts 114A, 114B may be configured to contact the wafer 108 at the intermediate time interval between the first time interval and the second time interval to stabilize the wafer 108 during the transition between the first time interval and the second time interval. Stated another way, the transition between the first time interval and the second time interval may include an intermediate time interval of transition when each of the plurality of contacts 114A, 114B are configured to contact the wafer 108/

Each of the plurality of contacts 114A, 114B may contact the wafer 108 at respective contact positions (e.g., points of interface or contact between a contact 114A, 114B and the wafer 108). Stated another way, the first subset 114A of contacts may contact the wafer 108 at a first subset of contact positions and the second subset 114B of contacts may contact the wafer 108 at a second subset of contact positions. Accordingly, the wafer 108 may be cleaned along the second subset of contact positions during the first time interval. Also, the wafer 108 may be cleaned along the first subset of contact positions during the second time interval. Also, during the intermediate time interval, the contacts 114A, 114B may contact the wafer 108 at both the first subset of contact positions and the second subset of contact positions.

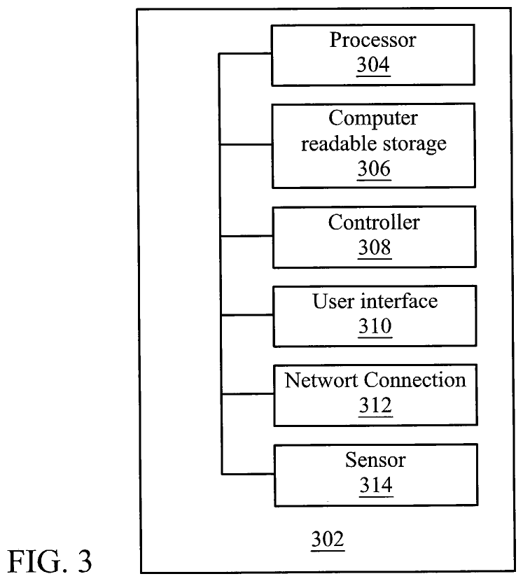

FIG. 3 is a block diagram of a dynamic contact cleaning chamber functional module of 302 the dynamic contact cleaning chamber 100, in accordance with some embodiments. The dynamic contact cleaning chamber 100 may also include various additional components (e.g., a pedestal, nozzle, contacts, and the like) that are discussed above but not illustrated in FIG. 3. The dynamic contact cleaning chamber functional module may include a processor 304. In further embodiments, the processor 304 may be implemented as one or more processors.

The processor 304 may be operatively connected to a computer readable storage module 306 (e.g., a memory and/or data store), a controller module 308 (e.g., a controller), a user interface module 310 (e.g., a user interface), a network connection module 312 (e.g., network interface), and a sensor module 314 (e.g., a sensor). In some embodiments, the computer readable storage module 306 may include dynamic contact cleaning chamber functional module system logic that may configure the processor 304 to perform various processes discussed herein. The computer readable storage may also store data, such as identifiers for a wafer or a wafer batch, identifiers for a dynamic contact cleaning chamber, identifiers for particular cleaning solutions, a time for a wafer cleaning session, a time for use of particular contact subsets, identifiers for different contact subsets, and any other parameter or information that may be utilized to perform the various processes discussed herein.

The dynamic contact cleaning chamber functional module 302 may include a controller module 308. The controller module 308 may be configured to control various physical apparatuses that control movement or functionality for a pedestal, wafer, and/or contact. For example, the controller module 308 may be configured to control movement or functionality for at least one of a robotic arm that moves the wafer, an actuator for the contact, a motor for the pedestal, and the like. For example, the controller module 308 may control a motor or actuator that may move or activate at least one of a robotic arm, contact, and/or pedestal. The controller may be controlled by the processor and may carry out aspects of the various processes discussed herein.

The dynamic contact cleaning chamber functional module 302 may also include the user interface module 310. The user interface module may include any type of interface for input and/or output to an operator of the dynamic contact cleaning chamber functional module 302, including, but not limited to, a monitor, a laptop computer, a tablet, or a mobile device, etc.

The network connection module 312 may facilitate a network connection of the dynamic contact cleaning chamber functional module 302 with various devices and/or components of the dynamic contact cleaning chamber functional module 302 that may communicate (e.g., send signals, messages, instructions, or data) within or external to the dynamic contact cleaning chamber functional module 302. In certain embodiments, the network connection module 312 may facilitate a physical connection, such as a line or a bus. In other embodiments, the network connection module 312 may facilitate a wireless connection, such as over a wireless local area network (WLAN) by using a transmitter, receiver, and/or transceiver. For example, the network connection module 312 may facilitate a wireless or wired connection with the sensor 314, the processor 304, the computer readable storage 306, and the controller 308.

In other embodiments, the cleaning session may be ended once a desired level of decontamination has occurred as determined via the sensor module 314 configured to sense for the level of decontamination. The sensor may be any type of sensor configured to determine whether decontamination or a sufficient amount of cleaning has occurred. In certain embodiments, the sensor may be a particulate sensor configured to sense for the level of decontamination. Accordingly, the cleaning session may be ended based on an output from the sensor module 314 indicating that the desired level of decontamination has occurred.

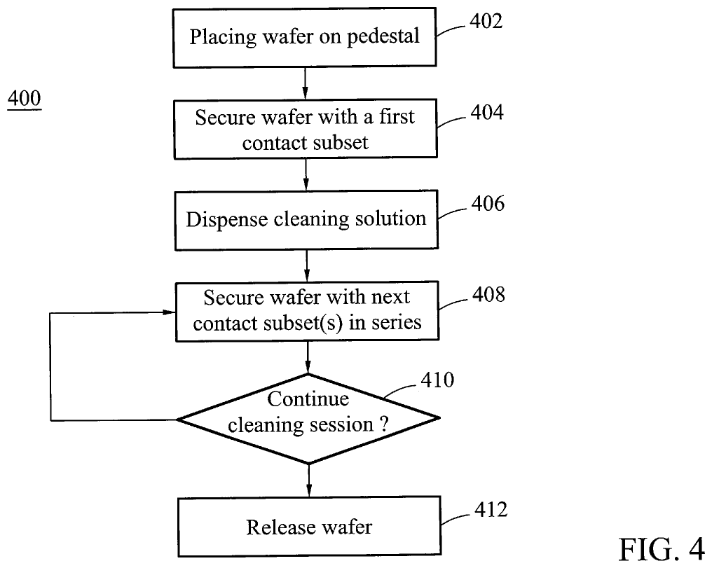

FIG. 4 is a flow chart of a dynamic contact cleaning chamber process 400, in accordance with some embodiments. The dynamic contact cleaning chamber process 400, may be performed by a dynamic contact cleaning chamber, as introduced above. It is noted that the process 400 is merely an example, and is not intended to limit the present disclosure. Accordingly, it is understood that additional operations may be provided before, during, and after the process 400 of FIG. 4, certain operations may be omitted, certain operations may be performed concurrently with other operations, and that some other operations may only be briefly described herein.

At operation 402, a wafer may be placed on a pedestal within a dynamic contact cleaning chamber. The wafer may be placed on the pedestal via a robotic arm that may move into and out of the enclosure of the dynamic contact cleaning chamber via a portal. The portal may be any region of the dynamic contact cleaning chamber configured to be opened and/or closed as desired to provide access to the enclosure region of the dynamic contact cleaning chamber. In certain embodiments, the pedestal may be an electrostatic pedestal configured to secure the wafer to the pedestal via electrostatic forces. In other embodiments, the pedestal may not be an electrostatic pedestal but may merely be an object on which the wafer may rest or be placed on. Then, contacts (as discussed above) may secure the wafer to the pedestal (e.g., while the wafer is resting on the pedestal).

At operation 404, the wafer may be secured to the pedestal via a first contact subset. The first contact subset may be a subset of contacts that may contact the wafer to secure the wafer during cleaning (e.g., during a wafer cleaning session). As noted above, the contacts may be dynamic contacts that change contact positions on the wafer over time. In this manner, the points of contacts or contact positions on the wafer may change over time in a single continuous cleaning session. It can be appreciated that a wafer may not be properly cleaned if the contact positions on the wafer are not released for cleaning at the contact positions. Accordingly, a wafer may have its contact positions cleaned when secured to a pedestal using dynamic contacts that change contact positions during a session of cleaning.

These contacts may secure the wafer along a periphery (e.g., a circumference) of the wafer. For example, a total number of contacts may contact the periphery of the wafer at respective contact positions on the wafer. However, different subsets of the total number of contacts may contact the periphery of the wafer at different intervals of time. For example, when the total number of contacts is six contacts, three of the six contacts may be of a first subset of the total number of contacts and the other three of the six contacts may be of a second subset of the total number of contacts.

At operation 406, a cleaning solution may be dispense on the secured wafer. A nozzle may be configured to deposit the cleaning solution on the wafer disposed during a cleaning session. This cleaning solution may be deionized water, or may be based on hydrogen peroxide. For example, at high pH values (basic) organic contamination and oxidizable particles may be removed by an oxidation process. At low pH (acidic) metal contamination may be desorbed from the water surface by forming a soluble complex.

In various embodiments, the cleaning solution may be one of a solution of hydrogen peroxide (H₂O₂) and sulfuric acid (H₂SO₄), a solution of hydrogen peroxide with choline ((CH₃)₃N(CH₂CH₂OH)OH), a solution of H₂O₂ and NH₄OH and a solution of H₂O₂ and HCl, a solution of a carboxylic group containing acid, such as citric acid, and deionized water. In addition, different cleaning solutions may be applied at different times during a cleaning session, such as where after applying a first cleaning solution, the cleaning process is followed by a deionized water rinse and spin dry.

In various embodiments, a cleaning session may include simultaneously rotating the wafer while a high pressure jet of the cleaning solution is sprayed on a process surface of the wafer. For example, one or more jet spray nozzles may sweep a spray of pressurized cleaning solution over the wafer process surface of the wafer, which is mounted on the pedestal. The dynamic contacts may be configured to contact the wafer at the periphery of the wafer to hold the wafer in place while pedestal rotates. In operation, for example the pressurized spray of cleaning solution is preferably about 10 pound force per square inch (PSI) to about 20 PSI and is applied over the process surface of the wafer preferably rotated at speeds of about 200 to about 1000 rpm.

At operation 408, the wafer may be secured with a next contact subset(s) in series. In certain embodiments, operation 408 may continue to repeat and cycle though a serial application of the contact subsets until the cleaning session has ended, as discussed below in connection with operation 410.

As noted above, the contacts may be dynamic contacts that change contact positions on the wafer over time. In this manner, the points of contacts or contact positions on the wafer may change over time in a single continuous cleaning session. For example, a total number of contacts may contact the periphery of the wafer at respective contact positions on the wafer. However, different subsets of the total number of contacts may contact the periphery of the wafer at a particular interval of time. Accordingly, after a first interval of time has passed when the wafer was secured with the first contact subset, the dynamic contact cleaning chamber may then secure the wafer with a next contact subset (e.g., a contact subset that is different than the first contact subset). In this manner, different contact subsets may contact a wafer in series so that not all of the contact subsets are utilized to contact and secure the wafer throughout a cleaning session. Rather, different contact subsets are utilized to contact and secure the wafer throughout the cleaning session.

At operation 410, a decision may be made as to whether the cleaning session has ended. In certain embodiments, the cleaning session may be ended after a certain amount of time has passed. In other embodiments, the cleaning session may be ended once a desired level of decontamination has occurred (e.g., as determined via a sensor configured to sense for the level of decontamination). Such a sensor may be conventional and will not be discussed in detail herein. However, the cleaning session may be ended based on an output from the sensor indicating that the desired level of decontamination has occurred. If the cleaning session as ended, the process 400 may proceed to operation 412. If the cleaning session has not ended, the process 400 may return to operation 408.

At operation 412, the wafer may be released upon the end of the cleaning session. For example, the wafer may be released by releasing all of the contacts from contacting the wafer (e.g., such that no contacts contact the wafer). Thus, the freed wafer may be removed from the dynamic contact cleaning chamber by a robotic arm that may move into and out of the enclosure of the dynamic contact cleaning chamber via the portal.

In certain embodiments, along with the cessation of cleaning solution dispensation, the pedestal may be slowed down to stop rotating at the end of the single cleaning session. In particular embodiments, the cleaning solution dispensation may be ended along with at the end of the cleaning session. However, in other embodiments, the cleaning session may still continue with rotation of the pedestal after cessation of cleaning solution dispensation, such as to dry the wafer after cleaning solution dispensation.

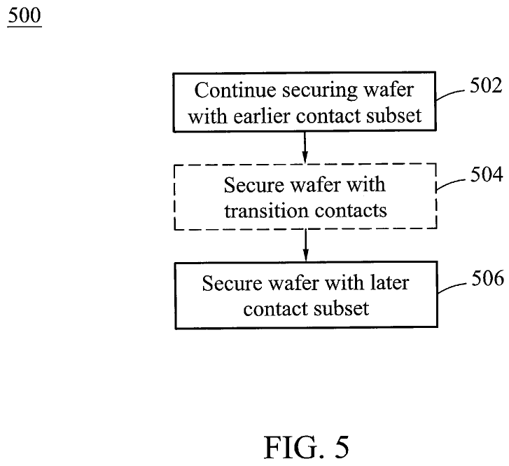

FIG. 5 is a flow chart of a process 500 for securing a wafer with a next contact subset(s) in series, in accordance with some embodiments. The process 500, may be performed by a dynamic contact cleaning chamber, as introduced above. It is noted that the process 500 is merely an example, and is not intended to limit the present disclosure. Accordingly, it is understood that additional operations may be provided before, during, and after the process 500 of FIG. 5, certain operations may be omitted, certain operations may be performed concurrently with other operations, and that some other operations may only be briefly described herein. In certain embodiments, the process 500 may continue to repeat and cycle though a serial application of the contact subsets until the cleaning session has ended.

At operation 502 the wafer may be secured with an earlier contact subset. The earlier contact subset may be a contact subset that secures the wafer prior to transition to a later contact subset. As noted above, the contacts may be dynamic contacts that change contact positions on the wafer over time. In this manner, the points of contacts or contact positions on the wafer may change over time in a single continuous cleaning session. For example, a total number of contacts may contact the periphery of the wafer at respective contact positions on the wafer. However, different subsets of the total number of contacts may contact the periphery of the wafer at a particular interval of time. Accordingly, after an earlier interval of time has passed when the wafer was secured with the earlier contact subset, the dynamic contact cleaning chamber may then secure the wafer with a later contact subset (e.g., a contact subset that is different than the earlier contact subset). In this manner, different contact subsets may contact a wafer in series so that not all of the contact subsets are utilized to contact and secure the wafer throughout a cleaning session. Rather, different contact subsets are utilized to contact and secure the wafer throughout the cleaning session.

At operation 504, optionally, as noted in doted lines, a transition subset of the contacts may contact the wafer during the transition (e.g., during an intermediate time interval) from utilizing the earlier contact subset to utilizing the later contact subset to secure the wafer within a single cleaning session. In certain embodiments, the transition subset may include all of the contacts within the earlier contact subset and the later contact subset. In further embodiments, the transition subset may be a distinct subset from any of the earlier or the later contact subsets. Stated another way, the transition subset may be a subset of contacts that is repeatedly applied (e.g., used to secure a wafer) during a transition between other subsets that are not transition subsets.

At operation 506, the wafer may be secured with the later contact subset. The later contact subset may be a contact subset that secures the wafer after the earlier contact subset. In certain optional embodiments, the later contact subset may be a contact subset that secures the wafer after the earlier contact subset and after the transition subset.

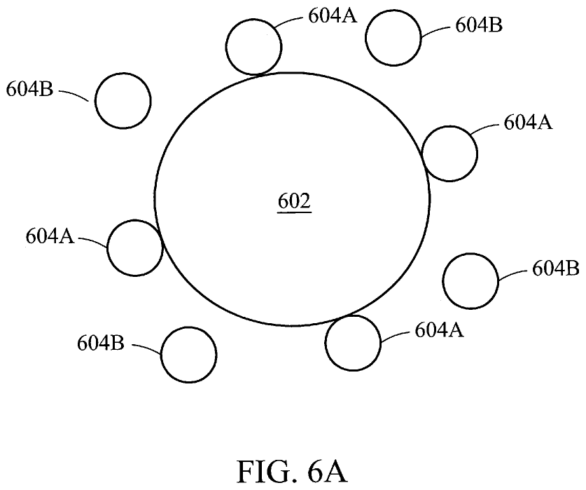

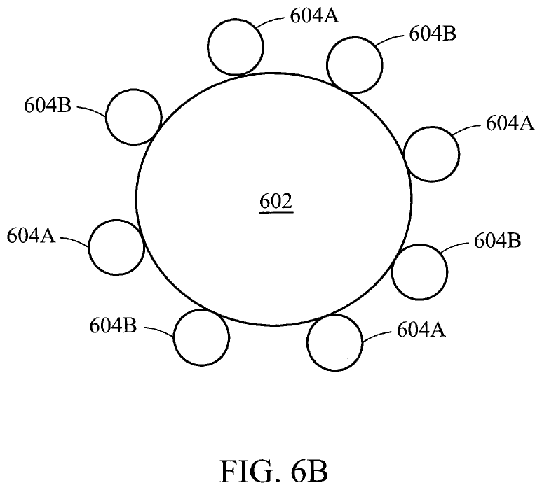

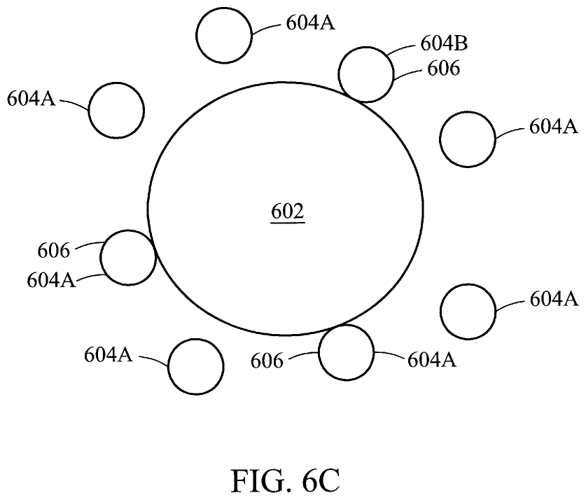

FIG. 6A illustrates a wafer 602 secured with a first contact subset 604A, in accordance with some embodiments. There may be eight total contacts 604A, 604B, with four contacts in the first contact subset 604A and four contacts 604B in the second contact subset. As illustrated, only the first contact subset 604A is in contact with the wafer 602 while the second contact subset 604B is not in contact with the wafer 602. In reference to the embodiment recited in FIG. 5, in various embodiments, the first contact subset 604A may be an earlier contact subset and the second contact subset 604B may be a later contact subset. However, in other embodiments, the second contact subset 604B may be the earlier contact subset while the first contact subset 604A may be the later contact subset.

FIG. 6B illustrates the wafer 602 secured with the all contact subsets during an intermediate time interval, in accordance with some embodiments. The intermediate time interval may immediately follow an earlier time interval. As noted above, there may be eight total contacts 604A, 604B, with four contacts in the first contact subset 604A and four contacts 604B in the second contact subset. As illustrated, both of the first contact subset 604A and the second contact subset 604B are in contact with the wafer 602 during this intermediate time interval. Stated another way, a transition subset may include each of the first and second contact subsets.

FIG. 6C illustrates the wafer 602 secured with a transition subset 606 distinct from the first contact subset 604A and the second contact subset 604B during an intermediate time interval, in accordance with some embodiments. In certain embodiments, the transition subset 606 may be employed in alternate embodiments to that illustrated in FIG. 6B. The intermediate time interval may immediately follow an earlier time interval. As noted above, there may be eight total contacts, with four contacts in the first contact subset 604A and four contacts 604B in the second contact subset. However, during the intermediate time interval, only the transition subset 606 contacts the wafer 602 during the transition time period. Stated another way, the transition subset 606 may not overlap in entirety with the first contact subset 604A or the second contact subset 604B.

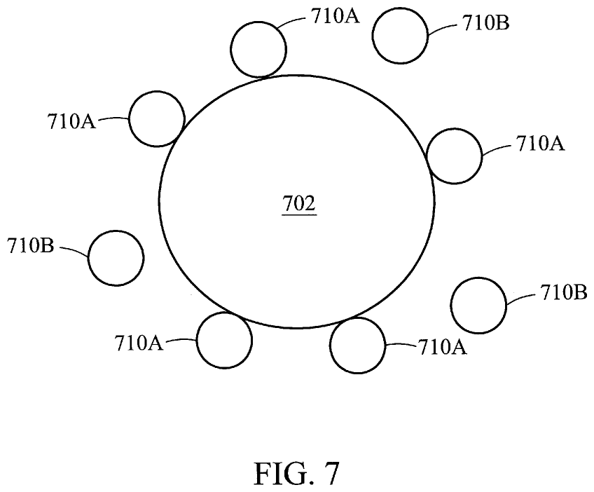

FIG. 7 illustrates a wafer 702 secured with a first contact subset 710A, in accordance with some embodiments. There may be eight total contacts 710A, 710B, with five contacts in the first contact subset 710A and three contacts 710B in the second contact subset. As illustrated, only the first contact subset 710A is in contact with the wafer 702 while the second contact subset 710B is not in contact with the wafer 702 during a particular time interval. In reference to the embodiment recited in FIG. 5, in various embodiments, the first contact subset 710A may be the earlier contact subset while the second contact subset 710B may be the later contact subset. However, in further embodiments, the first contact subset 710A may be the later contact subset while the second contact subset 710B may be the earlier contact subset.

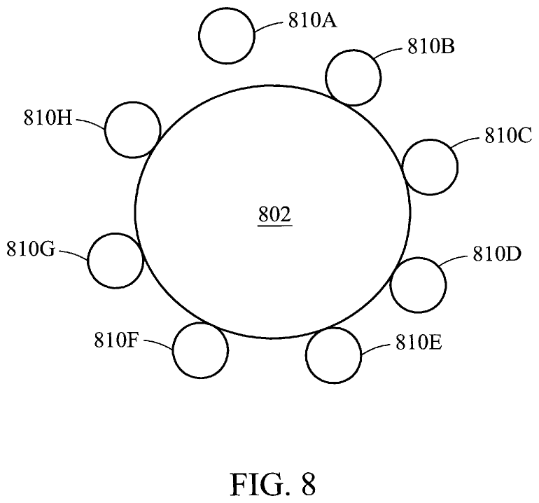

FIG. 8 illustrates a wafer 802 secured with a first contact subset 810A, in accordance with some embodiments. There may be eight total contacts 810A, 810B, 810C, 810D, 810E, 810F, 810G, and 81011. Each contact subset may be composed of all of the contacts except for a single contact. Also, each of the contact subsets may be configured to contact the wafer in a particular time interval. Furthermore, in certain embodiments, there may be no intermediate time interval (e.g., no transition subset).

For example, all of the contacts except contact 810A may be part of a first contact subset to contact the wafer during a first time interval; all of the contacts except contact 810B may be part of a second contact subset to contact the wafer during a second time interval; all of the contacts except contact 810C may be part of a third contact subset to contact the wafer during a third time interval; all of the contacts except contact 810D may be part of a fourth contact subset to contact the wafer during a fourth time interval; all of the contacts except contact 810E may be part of a fifth contact subset to contact the wafer during a fifth time interval; all of the contacts except contact 810F may be part of a sixth contact subset to contact the wafer during a sixth time interval; all of the contacts except contact 810G may be part of a seventh contact subset to contact the wafer during a seventh time interval; and all of the contacts except contact 810H may be part of an eighth contact subset to contact the wafer during an eighth time interval. Also, the contact subsets and associated time intervals may continue to cycle among themselves (e.g., where the eighth time interval is followed by a repeated first time interval) until the cleaning session is complete.

In an embodiment, a system includes: a pedestal configured to secure a wafer; a nozzle configured to deposit a cleaning solution on the wafer disposed on the pedestal during a cleaning session; and a plurality of contacts configured to secure the wafer to the pedestal while the cleaning solution is deposited on the wafer, wherein a first subset of the plurality of contacts is configured to contact the wafer at a first time interval and a second subset of the plurality of contacts is configured to contact the wafer at a second time interval.

In another embodiment, a method includes: cleaning a wafer disposed on a pedestal using a cleaning solution deposited on the wafer; securing the wafer to the pedestal using a first subset of a plurality of contacts during a first time interval; and securing the wafer to the pedestal using a second subset of the plurality of contacts during a second time interval, wherein the second time interval is different than the first time interval.

In another embodiment, a method includes: securing a wafer to a pedestal at a first subset of a plurality of contact positions during a first time interval; cleaning the wafer along a second subset of the plurality of contact positions during the first time interval; and securing the wafer to the pedestal at the second subset of the plurality of contact positions during a second time interval, wherein the second time interval is different than the first time interval.

The foregoing outlines features of several embodiments so that those ordinary skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

In this document, the term “module” as used herein, refers to software, firmware, hardware, and any combination of these elements for performing the associated functions described herein. Additionally, for purpose of discussion, the various modules are described as discrete modules; however, as would be apparent to one of ordinary skill in the art, two or more modules may be combined to form a single module that performs the associated functions according embodiments of the invention.

A person of ordinary skill in the art would further appreciate that any of the various illustrative logical blocks, modules, processors, means, circuits, methods and functions described in connection with the aspects disclosed herein can be implemented by electronic hardware (e.g., a digital implementation, an analog implementation, or a combination of the two), firmware, various forms of program or design code incorporating instructions (which can be referred to herein, for convenience, as “software” or a “software module), or any combination of these techniques. To clearly illustrate this interchangeability of hardware, firmware and software, various illustrative components, blocks, modules, circuits, and steps have been described above generally in terms of their functionality. Whether such functionality is implemented as hardware, firmware or software, or a combination of these techniques, depends upon the particular application and design constraints imposed on the overall system. Skilled artisans can implement the described functionality in various ways for each particular application, but such implementation decisions do not cause a departure from the scope of the present disclosure.

Furthermore, a person of ordinary skill in the art would understand that various illustrative logical blocks, modules, devices, components and circuits described herein can be implemented within or performed by an integrated circuit (IC) that can include a general purpose processor, a digital signal processor (DSP), an application specific integrated circuit (ASIC), a field programmable gate array (FPGA) or other programmable logic device, or any combination thereof. The logical blocks, modules, and circuits can further include antennas and/or transceivers to communicate with various components within the network or within the device. A general purpose processor can be a microprocessor, but in the alternative, the processor can be any conventional processor, controller, or state machine. A processor can also be implemented as a combination of computing devices, e.g., a combination of a DSP and a microprocessor, a plurality of microprocessors, one or more microprocessors in conjunction with a DSP core, or any other suitable configuration to perform the functions described herein.

Conditional language such as, among others, “can,” “could,” “might” or “may,” unless specifically stated otherwise, are otherwise understood within the context as used in general to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Additionally, persons of skill in the art would be enabled to configure functional entities to perform the operations described herein after reading the present disclosure. The term “configured” as used herein with respect to a specified operation or function refers to a system, device, component, circuit, structure, machine, etc. that is physically or virtually constructed, programmed and/or arranged to perform the specified operation or function.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

It should be emphasized that many variations and modifications may be made to the above-described embodiments, the elements of which are to be understood as being among other acceptable examples. All such modifications and variations are intended to be included herein within the scope of this disclosure and protected by the following claims.

What is claimed is:

1. A system, comprising:
a pedestal configured to secure a wafer;
a nozzle configured to deposit a cleaning solution on the wafer disposed on the pedestal during a cleaning session; and
a plurality of contacts configured to secure the wafer to the pedestal while the cleaning solution is deposited on the wafer, wherein a first subset of the plurality of contacts is configured to contact the wafer at a first time interval and a second subset of the plurality of contacts is configured to contact the wafer at a second time interval.

2. The system of claim 1, wherein the first time interval and the second time interval are continuous.

3. The system of claim 1, wherein the plurality of contacts are all configured to contact the wafer at a third time interval between the first time interval and the second time interval.

4. The system of claim 1, wherein the first subset of the plurality of contacts comprise different contacts than the second subset of the plurality of contacts.

5. The system of claim 1, wherein the pedestal is configured to be rotated.

6. The system of claim 1, wherein the plurality of contacts are each cylindrical in shape.

7. The system of claim 1, wherein each of the plurality of contacts are configured to contact the wafer at a circumference of the wafer.

8. The system of claim 1, wherein the first subset of the plurality of contacts comprise contacts that are also part of the second subset of the plurality of contacts.

9. A method, comprising:
cleaning a wafer disposed on a pedestal using a cleaning solution deposited on the wafer;
securing the wafer to the pedestal using a first subset of a plurality of contacts during a first time interval; and
securing the wafer to the pedestal using a second subset of the plurality of contacts during a second time interval, wherein the second time interval is different than the first time interval.

10. The method of claim 9, wherein the second time interval is after the first time interval.

11. The method of claim 9, further comprising:
securing the wafer to the pedestal using the first subset of the plurality of contacts and the second subset of the plurality of contacts at a third time interval between the first time interval and the second time interval.

12. The method of claim 11, wherein the second time interval immediately follows the third time interval and the third time interval immediately follows the first time interval.

13. The method of claim 9, further comprising:
rotating the pedestal.

14. The method of claim 9, further comprising:
dispensing the cleaning solution over the wafer.

15. A method, comprising:
securing a wafer to a pedestal at a first subset of a plurality of contact positions during a first time interval;
cleaning the wafer along a second subset of the plurality of contact positions during the first time interval; and
securing the wafer to the pedestal at the second subset of the plurality of contact positions during a second time interval, wherein the second time interval is different than the first time interval.

16. The method of claim 15, further comprising:
cleaning the wafer along the first subset of the plurality of contact positions during the second time interval.

17. The method of claim 15, wherein the cleaning the wafer comprises applying a cleaning solution to the wafer.

18. The method of claim 15, further comprising:
securing the wafer to the pedestal at the first subset of the plurality of contact positions and at the second subset of the plurality of contact positions during a third time interval between the second time interval and the first time interval.

19. The method of claim 15, wherein the first subset of the plurality of contact positions is of a greater number than the second subset of the plurality of contact positions.

20. The method of claim 15, wherein the second subset of the plurality of contact positions is of a smaller number than the first subset of the plurality of contact positions.
